(19) United States
(12) Patent Application Publication
(10) Pub. No.: US 2026/0282438 A1
(43) Pub. Date: Sep. 17, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Junpei HISADA, Nonoichi Ishikawa (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/366,682

(22) Filed: Oct. 23, 2025

(30) Foreign Application Priority Data
Mar. 14, 2025 (JP) 2025-041285

(51) Int. Cl. H10D 30/66; H10D 62/10; H10D 64/00

(52) U.S. Cl. CPC H10D 30/668; H10D 30/665; H10D 62/102; H10D 62/126; H10D 64/112; H10D 64/117

(57) ABSTRACT

A semiconductor member includes a first semiconductor region, a second semiconductor region, and a third semiconductor region aligned from a first side to a second side. The first semiconductor region is electrically connected to a source electrode. At least a part of the second semiconductor region faces a gate electrode in a second direction perpendicular to a first direction. The first semiconductor region has a plurality of first divisions and a plurality of second divisions when seen in the first direction. The first divisions are provided from a surface to a position of a first depth. The second divisions are provided from the surface to a position of a second depth greater than the first depth. The second semiconductor region is provided from lower ends of the first divisions and lower ends of the second divisions to a position of a third depth.

### CROSS-REFERENCE TO RELATED APPLICATION

This application is based upon and claims the benefit of priority from Japanese Patent Application No. 2025-041285, filed on Mar. 14, 2025; the entire contents of which are incorporated herein by reference.

### FIELD

Embodiments described herein relate generally to a semiconductor device.

### BACKGROUND

In a power metal-oxide-semiconductor field-effect transistor (MOSFET), reduction of on-resistance has been achieved by increasing a channel density and decreasing a channel resistance. However, there was a problem that the increase in channel density caused by miniaturization narrows a safety operating area (SOA).

### BRIEF DESCRIPTION OF THE DRAWINGS

FIG. 1 is a cross-sectional view of a semiconductor device of a first embodiment when seen from above.

FIG. 2 is a cross-sectional view of the semiconductor device of the first embodiment along line II-II in FIG. 1.

FIG. 3 is a cross-sectional view of the semiconductor device of the first embodiment along line III-III in FIG. 1.

FIG. 4 is a cross-sectional view of the semiconductor device of the first embodiment along line IV-IV in FIG. 1.

FIG. 5 is a graph expressing a relationship between a gate voltage and a drain current of a general semiconductor device.

FIG. 6 is a graph expressing a relationship between a gate voltage and a drain current when miniaturization of the general semiconductor device is achieved.

FIG. 7 is a graph expressing a relationship between a gate voltage and a drain current of the semiconductor device of the first embodiment.

FIG. 8 is a cross-sectional view of a semiconductor device of a second embodiment when seen from above.

FIG. 9 is a cross-sectional view of the semiconductor device of the second embodiment along line IX-IX in FIG. 8.

FIG. 10 is a cross-sectional view of a semiconductor device of a third embodiment from above.

FIG. 11 is a cross-sectional view of the semiconductor device of the third embodiment along line XI-XI in FIG. 10.

FIG. 12 is a cross-sectional view of a semiconductor device of a fourth embodiment.

FIG. 13 is a cross-sectional view of a semiconductor device of a fifth embodiment when seen from above.

FIG. 14 is a cross-sectional view of the semiconductor device of the fifth embodiment along line XIV-XIV in FIG. 13.

### DETAILED DESCRIPTION

A semiconductor device of an embodiment has a source electrode, a drain electrode, a gate electrode, and an insulating portion. The semiconductor member is provided with a first concave portion. The first concave portion is recessed from a surface in a first direction on a first side to a second side opposite to the first side. The source electrode is located on the first side of the semiconductor member. The drain electrode is located on the second side of the semiconductor member. At least a part of the gate electrode is located in the first concave portion. The insulating portion is located in the first concave portion. The insulating portion insulates the semiconductor member from the gate electrode. The semiconductor member includes a first semiconductor region of a first conductivity type, a second semiconductor region of a second conductivity type, and a third semiconductor region of a first conductivity type. The first semiconductor region is electrically connected to the source electrode. The second semiconductor region is located on the second side of the first semiconductor region. At least a part of the second semiconductor region faces the gate electrode in a second direction perpendicular to the first direction. The third semiconductor region is located on the second side of the second semiconductor region. The first semiconductor region has a plurality of first divisions and a plurality of second divisions when seen in the first direction. The first divisions are provided from the surface to a position of a first depth. The second divisions are provided from the surface to a position of a second depth greater than the first depth. An end on the second side of the second semiconductor region is provided below the first divisions and the second divisions and at a third depth from the surface.

Hereinafter, the semiconductor device of the embodiment will be described with reference to the accompanying drawings.

### First Embodiment

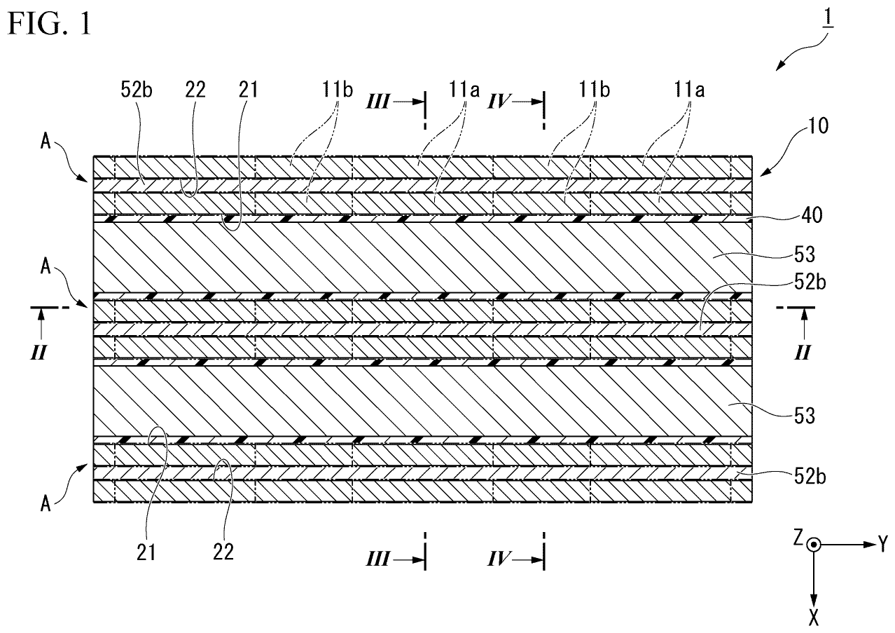

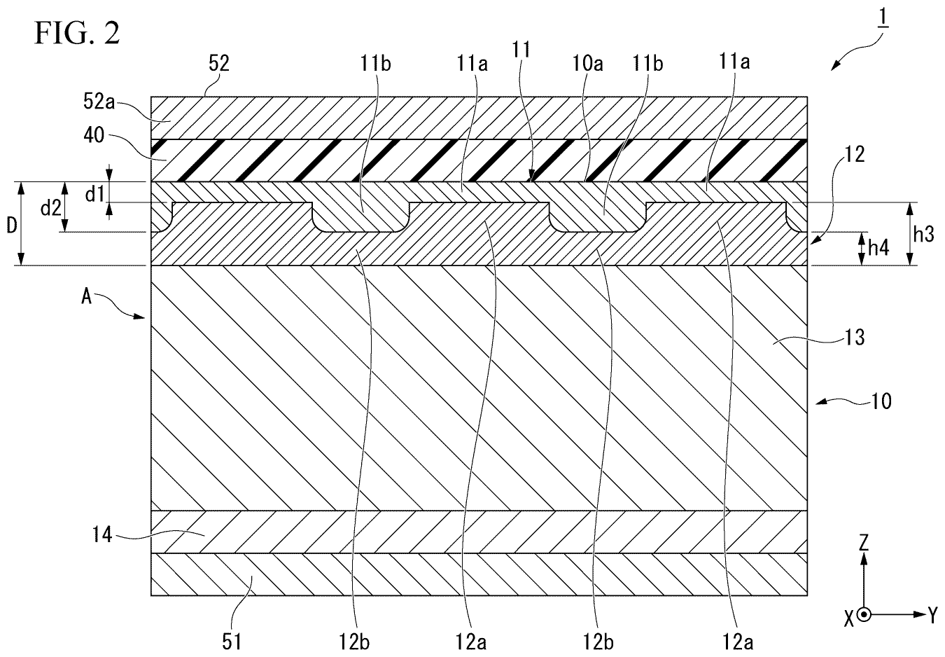

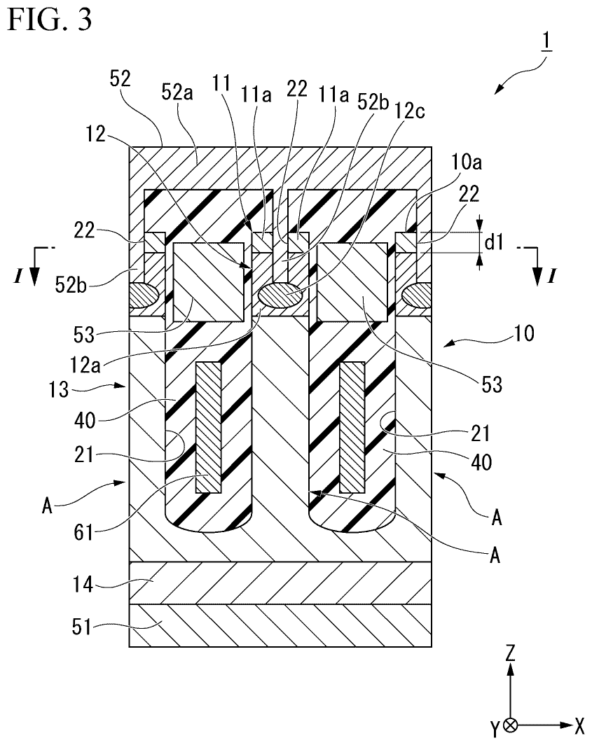

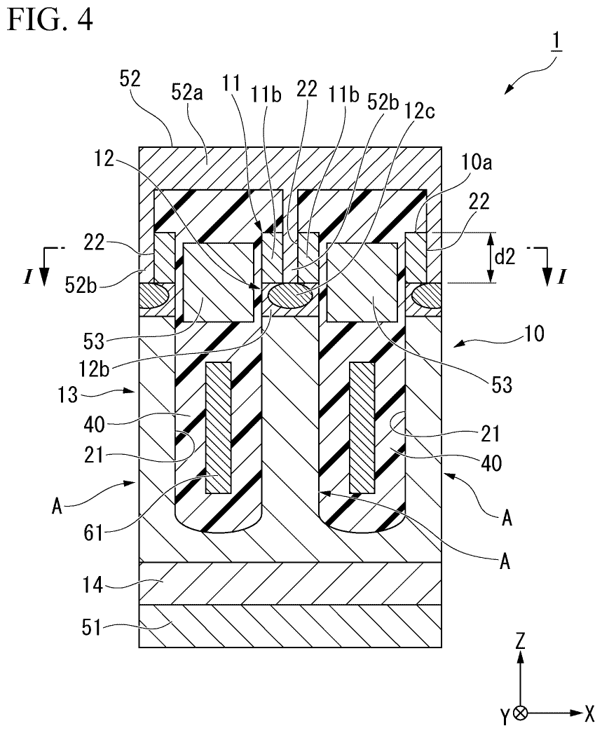

FIG. 1 is a cross-sectional view of a semiconductor device 1 of a first embodiment when seen from above. FIG. 2 is a cross-sectional view of the semiconductor device 1 of the first embodiment along line II-II in FIG. 1. FIG. 3 is a cross-sectional view of the semiconductor device 1 of the first embodiment along line III-III in FIG. 1. FIG. 4 is a cross-sectional view of the semiconductor device 1 of the first embodiment along line IV-IV in FIG. 1. Further, FIG. 1 is a cross-sectional view along line I-I in FIG. 3 and FIG. 4.

The drawings show an X axis, a Y axis, and a Z axis as appropriate. The X axis, the Y axis, and the Z axis are perpendicular to each other.

In this specification, a term “direction” is a concept that encompasses two directions (one side and the other side) that face opposite each other. In the following embodiment, a direction parallel to the Z axis corresponds to “a first direction,” a direction parallel to the X axis corresponds to “a second direction” and a direction parallel to the Y axis corresponds to “a third direction.” Accordingly, a first direction Z, a second direction X, and a third direction Y are three directions crossing each other. In the specification, a side (+Z) in the first direction Z facing an arrow of the Z axis is referred to as an upper side or a first side, and a side (−Z) in the first direction Z opposite to an arrow of the Z axis is referred to as a lower side or a second side. Further, in this specification, the concepts of “upper” and “lower” do not necessarily indicate a relationship with the direction of gravity.

In the following description, notations such as n, n⁺, n⁻, p, p⁺, p⁻, and the like, may be used. These notations represent a relative level in carrier concentration in each conductivity type. That is, n⁺ indicates that an n type carrier concentration is relatively higher than that of n, and n⁻ indicates that the n type carrier concentration is relatively lower than that of n.

In the specification, a carrier concentration of the semiconductor region can be measured using, for example, a cyclic voltammetry (CV) measuring instrument, or capacitance-voltage characteristic measurement. In addition, the carrier concentration of the semiconductor region may be calculated from an impurity concentration measured using, for example, secondary ion mass spectrometry (SIMS). A relative magnitude relationship between the carrier concentrations of the two semiconductor regions can be determined using, for example, scanning capacitance microscopy (SCM). In addition, a distribution and absolute values of the carrier concentrations can be measured using, for example, spreading resistance analysis (SRA).

As shown in FIG. 3 and FIG. 4, the semiconductor device 1 according to the embodiment includes a semiconductor member 10, a drain electrode 51, a source electrode 52, a plurality of gate electrodes 53, a plurality of field plate portions 61, and an insulating portion 40.

### Semiconductor Member

The semiconductor member 10 contains at least one selected from the group consisting of, for example, silicon (Si), nitride semiconductor (for example, GaN or the like), silicon carbide (SiC), and oxide semiconductor (for example, GaO).

The semiconductor member 10 is in the form of a substrate with the first direction Z as its thickness direction. The drain electrode 51 is located below the semiconductor member 10. In addition, the source electrode 52 is located above the semiconductor member 10. That is, the semiconductor member 10 is sandwiched between the drain electrode 51 and the source electrode 52 in the first direction Z. In addition, a direction from the drain electrode 51 to the source electrode 52 is along the first direction Z.

The semiconductor member 10 is provided with a plurality of first concave portions 21 and a plurality of second concave portions 22. The first concave portions 21 and the second concave portions 22 are recessed downward from an upper surface 10a of the semiconductor member 10. The first concave portions 21 are formed deeper than the second concave portions 22. As shown in FIG. 1, each of the first concave portions 21 and the second concave portions 22 is a groove portion extending in the third direction Y. The first concave portions 21 and the second concave portions 22 are alternately arranged in the second direction X. In the following description, a region between the first concave portions 21 adjacent to each other in the second direction X is referred to as an inter-recess region A. In the embodiment, the second concave portion 22 is provided in the inter-recess region A.

The semiconductor member 10 of the embodiment includes a third semiconductor region 13 of a first conductivity type, a second semiconductor region 12 of a second conductivity type, a first semiconductor region 11 of a first conductivity type, and a fourth semiconductor region 14 of a first conductivity type. The first semiconductor region 11, the second semiconductor region 12, the third semiconductor region 13, and the fourth semiconductor region 14 are formed in a layered shape in the first direction Z. These semiconductor regions are disposed from top to bottom in the order of the first semiconductor region 11, the second semiconductor region 12, the third semiconductor region 13, and the fourth semiconductor region 14.

The first conductivity type and second conductivity type are either n type or p type. In the embodiment, the first conductivity type is an n type, and the second conductivity type is a p type. However, the first conductivity type may be a p type, and the second conductivity type may be an n type.

The first semiconductor region 11 is, for example, an n⁺ region. A carrier concentration of the first conductivity type in the first semiconductor region 11 is higher than a carrier concentration of the first conductivity type in the third semiconductor region 13. The first semiconductor region 11 is in contact with the source electrode 52. Accordingly, the first semiconductor region 11 is electrically connected to the source electrode 52.

The first semiconductor region 11 is provided in the inter-recess region A. In addition, in the embodiment, the second concave portion 22 is provided in the inter-recess region A. Accordingly, an upper portion of the inter-recess region A is further divided into two regions by the second concave portion 22. The first semiconductor region 11 is provided in each of the two regions divided by the second concave portion 22.

As shown in FIG. 1, the first semiconductor region 11 has a plurality of first divisions 11a and a plurality of second divisions 11b that are alternately arranged in the third direction Y when seen in the first direction Z. As shown in FIG. 3, the first divisions 11a are provided from the upper surface 10a of the semiconductor member 10 to a position of a first depth d1. Meanwhile, as shown in FIG. 4, the second divisions 11b are provided from the upper surface 10a of the semiconductor member 10 to a position of a second depth d2. As shown in FIG. 2, the second depth d2 is greater than the first depth d1 (d2>d1).

As shown in FIG. 1, in the embodiment, in one inter-recess region A, the first divisions 11a and the second divisions 11b are alternately arranged in the third direction Y. That is, when the semiconductor device 1 of the embodiment is seen in the first direction, the plurality of first divisions 11a and the plurality of second divisions 11b are periodically disposed. In the embodiment, when seen in the first direction Z, a boundary between the first divisions 11a and the second divisions 11b is located on the same straight line in the plurality of inter-recess regions A. In addition, the first divisions 11a disposed in the inter-recess regions A adjacent to each other in the second direction X are arranged in the second direction X. Similarly, the second divisions 11b disposed in the inter-recess regions A adjacent to each other in the second direction X are arranged in the second direction X.

In the embodiment, an area of each of the first divisions 11a when seen in the first direction Z is greater than an area of one of the second divisions 11b when seen in the first direction Z. For this reason, a sum of areas of the plurality of first divisions 11a when seen in the first direction Z is greater than a sum of areas of the plurality of second divisions 11b when seen in the first direction Z.

The second semiconductor region 12 is, for example, a p region. The second semiconductor region 12 is located below the first semiconductor region 11. The second semiconductor region 12 is located above a bottom portion of the first concave portion 21. The second semiconductor region 12 is provided in the inter-recess region A. A part of the second semiconductor region 12 is located above a bottom portion of the second concave portion 22, and the other portion is located below the bottom portion of the second concave portion 22. At least a part of the second semiconductor region 12 is located between the first concave portion 21 and the second concave portion 22 in the second direction X. In addition, at least a part of the second semiconductor region 12 is located between the source electrode 52 and the gate electrode 53 in the second direction X.

The second semiconductor region 12 of the embodiment is provided with a partial region 12c formed along the bottom portion of the second concave portion 22. The partial region 12c is a region in the second semiconductor region 12 in which the carrier concentration is increased compared to the other region. The partial region 12c is, for example, a p⁺ region. The partial region 12c achieves reduction in the connection resistance between the source electrode 52 and the second semiconductor region 12. For this reason, the partial region 12c may be omitted, and the second semiconductor region 12 may have a uniform carrier concentration.

As shown in FIG. 2, the lower end of the second semiconductor region 12 of the embodiment is provided to a position of a depth (third depth) D below the first semiconductor region 11. That is, an end on the lower side of the second semiconductor region 12 is provided below the first divisions 11a and the second divisions 11b. And the end on the lower side of the second semiconductor 12 is provided at the depth D from the surface 10a of the semiconductor member 10.

Here, in the second semiconductor region 12, a division below the first division 11a is referred to as the third division 12a, and a division below the second division 11b is referred to as the fourth division 12b. That is, the second semiconductor region 12 is provided with the third divisions 12a and the fourth divisions 12b.

As described above, the lower end of the second semiconductor region 12 is located at the depth D from the surface 10a of the semiconductor member 10. That is, lower end portions of the third divisions 12a and the fourth divisions 12b are located on the same plane (X-Y plane) perpendicular to the first direction Z. Accordingly, a dimension h3 of the third division 12a in the first direction Z is greater than a dimension h4 of the fourth division 12b in the first direction Z.

The third semiconductor region 13 shown in FIG. 3 and FIG. 4 is, for example, an n region. The third semiconductor region 13 is located below the second semiconductor region 12. A part of the third semiconductor region 13 is located above the bottom portion of the first concave portion 21, and the other portion is located below the bottom portion of the first concave portion 21. The third semiconductor region 13 is located below the bottom portion of the second concave portion 22.

The fourth semiconductor region 14 is, for example, an n⁺ region. A carrier concentration of the first conductivity type in the fourth semiconductor region 14 is higher than a carrier concentration of the first conductivity type in the third semiconductor region 13. The fourth semiconductor region 14 is provided between the drain electrode 51 and the third semiconductor region 13 in the first direction Z. That is, the fourth semiconductor region 14 is located below the third semiconductor region 13.

The fourth semiconductor region 14 is in contact with the drain electrode 51. The fourth semiconductor region 14 is electrically connected to the drain electrode 51. According to the embodiment, by providing the fourth semiconductor region 14 having a high carrier concentration in the semiconductor member 10, the resistance of the electrical connection of the drain electrode 51 can be reduced. Accordingly, for example, the on-resistance of the semiconductor device 1 can be reduced. The fourth semiconductor region 14 may be omitted.

### Drain Electrode

The drain electrode 51 is located below the semiconductor member 10. The drain electrode 51 covers a lower surface of the semiconductor member 10. The drain electrode 51 contains at least one selected from the group consisting of, for example, Al, Cu, Mo, W, Ta, Co, Ru, Ti, Ni, Au, and Pt.

### Source Electrode

The source electrode 52 is located above the semiconductor member 10. The source electrode 52 has an interconnection layer 52a, and a contact portion 52b. The source electrode 52 contains at least one selected from the group consisting of, for example, Ti, TiN, Ni, W, Mo, Ta, Zr, Al, Au, Sn, V, Re, Os, Ir, Pt, Pd, Rh, Ru, Nb, Sr and Hf.

The contact portion 52b is located in the second concave portion 22. That is, a part of the source electrode 52 of the embodiment is located in the second concave portion 22. As shown in FIG. 1, the contact portion 52b extends in a direction in which the second concave portion 22 extends (the third direction Y) in the second concave portion 22. As shown in FIG. 3 and FIG. 4, the gate electrode 53 faces the contact portion 52b in the second direction X. At least a part of the second semiconductor region 12 is disposed between the contact portion 52b and the gate electrode 53.

The interconnection layer 52a is located above the contact portion 52b and connected to the contact portion 52b. In addition, the interconnection layer 52a is provided above the surface 10a of the semiconductor member 10.

### Gate Electrode

The gate electrode 53 is located in the first concave portion 21. At least a part of the gate electrode 53 may be located in the first concave portion 21. As shown in FIG. 1, the gate electrode 53 extends in a direction in which the first concave portion 21 extends (the third direction Y) in the first concave portion 21. The gate electrode 53 and the contact portion 52b are disposed side by side in the second direction X.

The gate electrode 53 contains, for example, conductive silicon, or polysilicon. As shown in FIG. 3 and FIG. 4, the gate electrode 53 is insulated from the semiconductor member 10 by the insulating portion 40.

In the semiconductor device 1 of the embodiment, current flowing between the drain electrode 51 and the source electrode 52 is controlled by the potential of the gate electrode 53. The potential of the gate electrode 53 is based on the potential of, for example, the source electrode 52.

### Field Plate Portion

The field plate portion 61 is located in the first concave portion 21. At least a part of the field plate portion 61 may be located in the first concave portion 21.

The field plate portion 61 is formed of a conductive material. The field plate portion 61 contains, for example, conductive silicon, or polysilicon. The field plate portion 61 is insulated from the semiconductor member 10 by the insulating portion 40.

The field plate portion 61 extends in the first direction Z and the third direction Y in the first concave portion 21. The field plate portion 61 is electrically connected to the source electrode 52 via a connecting portion (not shown) and has the same potential as the source electrode 52.

### Insulating Portion

The insulating portion 40 is located in the first concave portion 21. At least a part of the insulating portion 40 functions as a gate insulating film that surrounds the gate electrode 53, and insulates the gate electrode 53 from the source electrode 52, the gate electrode 53 from the field plate portion 61, and the gate electrode 53 from the semiconductor member 10. In addition, at least a part of the insulating portion 40 surrounds the field plate portion 61, and insulates the field plate portion 61 from the semiconductor member 10. The insulating portion 40 contains at least one selected from the group consisting of, for example, silicon oxide, silicon nitride, and silicon oxynitride.

### Effects

The semiconductor device 1 of the embodiment includes the semiconductor member 10, the source electrode 52, the drain electrode 51, the gate electrodes 53, and the insulating portion 40. The semiconductor member 10 is provided with the first concave portions 21 recessed downward from the upper surface 10a. The source electrode 52 is located above the semiconductor member 10. The drain electrode 51 is located below the semiconductor member 10. At least a part of the gate electrode 53 is located in the first concave portion 21. The insulating portion 40 is located in the first concave portion 21 and insulates the semiconductor member 10 from the gate electrode 53. The semiconductor member 10 includes the first semiconductor region of the first conductivity type, the second semiconductor region of the second conductivity type, and the third semiconductor region of the first conductivity type. The first semiconductor region 11 is located on the upper end portion of the semiconductor member 10. The first semiconductor region 11 is electrically connected to the source electrode 52. The second semiconductor region 12 is located below the first semiconductor region 11. At least a part of the second semiconductor region 12 faces the gate electrode 53 in the second direction perpendicular to the first direction Z. The third semiconductor region 13 is located below the second semiconductor region 12. The first semiconductor region 11 has the plurality of first divisions 11a and the plurality of second divisions 11b when seen in the first direction Z. The plurality of first divisions 11a are provided from the surface 10a to the position of the first depth d1. The plurality of second divisions 11b are provided from the surface 10a to the position of the second depth d2 greater than the first depth d1. An end on the lower side of the second semiconductor region 12 is provided below the first divisions 11a and the second divisions 11b and at the depth D from the surface 10a.

According to the embodiment, by providing the first divisions 11a and the second divisions 11b, which have different positions of the lower end portions, in the first semiconductor region 11, the two divisions (the third divisions 12a and the fourth divisions 12b) with different dimensions in the first direction Z can be formed in the second semiconductor region 12 below the first semiconductor region 11. Accordingly, the gate threshold voltages (hereinafter simply referred to as thresholds) of the two divisions of the second semiconductor region 12 can be made different. That is, the semiconductor device 1 has two divisions with different gate threshold voltages Vth1 and Vth2. Here, in the two divisions of the second semiconductor region 12, the first threshold of the fourth division 12b, where the dimension h4 of the first direction Z is small, is defined as Vth1, and the second threshold of the third division 12a, where the dimension h3 of the first direction Z is large, is defined as Vth2 (Vth1<Vth2).

In the semiconductor device 1 of the embodiment, the case where a positive voltage is applied to the drain electrode 51 and to the source electrode 52 while the voltage applied to the gate electrode 53 is gradually increased is considered. When the gate voltage is lower than the first threshold Vth1, no current flows through either the third divisions 12a or the fourth divisions 12b, and the entire second semiconductor region 12 is in the OFF state. By increasing the gate voltage and causing the gate voltage to reach the first threshold Vth1, the fourth division 12b enters the ON state, but the third division 12a remains in the OFF state. Further, when the gate voltage is increased and reaches the second threshold Vth2, the third divisions 12a also enter the ON state, and the entire second semiconductor region 12 enters the ON state. In this way, the semiconductor device 1 of this embodiment is provided with two gate threshold voltages Vth1 and Vth2.

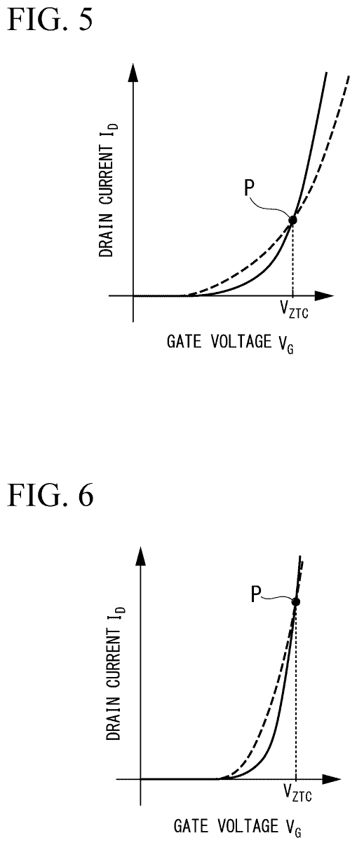

FIG. 5 is a graph expressing a relationship between a gate voltage V_{G} and a drain current I_{D} in a general semiconductor device. In addition, a solid line graph shows the change in the drain current I_{D} at a room temperature, and the dotted line graph shows the change in the drain current I_{D} at a temperature higher than the room temperature (hereinafter, simply referred to as a high temperature).

As can be seen from the two graphs in FIG. 5, the change in the drain current I_{D} at the room temperature is different from the change in the drain current I_{D} at the high temperature. In addition, these graphs cross each other at an intersection point P. The gate voltage V_{G} in the intersection point P is referred to as a zero-temperature coefficient voltage V_{ZTC}.

The drain current I_{D} has a positive temperature coefficient with respect to the temperature change at the gate voltage V_{G} that is lower than the zero-temperature coefficient voltage V_{ZTC}. In addition, the drain current I_{D} has a negative temperature coefficient with respect to the temperature change at the gate voltage V_{G} higher than the zero-temperature coefficient voltage V_{ZTC}. In the region where the gate voltage V_{G} is lower than the zero-temperature coefficient voltage V_{ZTC}, when the temperature rises due to heat generation caused by the flow of current, the drain current I_{D} increases, and the temperature rises further, causing the drain current I_{D} to increase, resulting in positive feedback and making thermal runaway more likely to occur.

FIG. 6 is a view showing a graph expressing a relationship between the gate voltage V_{G} and the drain current I_{D} when miniaturization of the general semiconductor device showing characteristics of FIG. 5 is achieved. As can be seen by comparing FIG. 5 and FIG. 6, miniaturizing the semiconductor device increases the zero-temperature coefficient voltage V_{ZTC} and the drain current I_{D} at the intersection point P. For this reason, when the general semiconductor device is miniaturized, thermal runaway becomes more likely to occur, resulting in a narrower safety operating area.

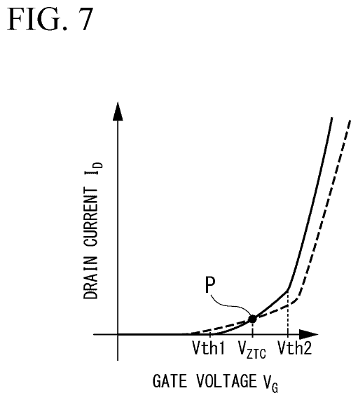

FIG. 7 is a graph expressing a relationship between the gate voltage V_{G} and the drain current I_{D} of the semiconductor device 1 according to the embodiment. That is, a solid line graph shown in FIG. 7 expresses a relationship at the room temperature, and the dotted line graph expresses a relationship at the temperature (high temperature) higher than the room temperature.

As described above, in the semiconductor device 1 of the embodiment, when the gate voltage V_{G} is lower than the first threshold Vth1, the third divisions 12a and the fourth divisions 12b are both in the OFF state, and no current flows through the semiconductor member 10. In addition, when the gate voltage V_{G} is the first threshold Vth1 or more and less than the second threshold Vth2, the fourth divisions 12b are in the ON state and current flows, but the third divisions 12a remain in the OFF state. Further, when the gate voltage V_{G} is equal to or greater than the second threshold Vth2, the third divisions 12a and the fourth divisions 12b are both in the ON state. In this way, according to the semiconductor device 1 of the embodiment, by providing the two gate threshold voltages Vth1 and Vth2, the rise of the drain current I_{D} with respect to the gate voltage V_{G} can be made gradual.

The zero-temperature coefficient voltage V_{ZTC} at the intersection point P in FIG. 7 is located between the first threshold Vth1 and the second threshold Vth2. According to the embodiment, the zero-temperature coefficient voltage V_{ZTC} can be decreased. Eventually, it is possible to prevent thermal runaway and expand the safety operating area.

In the semiconductor device 1 of the embodiment, a sum of areas of the plurality of first divisions 11a when seen in the first direction Z is greater than a sum of areas of the plurality of second divisions 11b when seen in the first direction Z. According to the embodiment, a sum of areas of the third divisions 12a located below the first divisions 11a can be greater than a sum of areas of the fourth divisions 12b located below the second divisions 11b. For this reason, it is possible to suppress the drain current I_{D} when only the fourth divisions 12b are in the ON state. That is, in FIG. 7, it is possible to make a slope of the graph between the first threshold Vth1 and the second threshold Vth2 even gentler. Eventually, this allows the rise of the drain current I_{D} relative to the gate voltage V_{G} to be made gradual, making it difficult for thermal runaway to occur and expanding the safety operating area.

As shown in FIG. 1, in the semiconductor device 1 of the embodiment, the plurality of first divisions 11a and the plurality of second divisions 11b are periodically disposed when seen in the first direction Z. Accordingly, the third divisions 12a and the fourth divisions 12b are also periodically disposed. For this reason, when the gate voltage V_{G} is the first threshold Vth1 or more and the second threshold Vth2 or less, the fourth divisions 12b through which a current flows and the third divisions 12a through which no current flows can be arranged separately. Accordingly, a local temperature rise in the second semiconductor region 12 can be suppressed.

In the semiconductor device 1 of the embodiment, the first concave portions 21 and the gate electrodes 53 are each provided in multiple locations. The plurality of first concave portions 21 and the plurality of gate electrodes 53 are arranged in the second direction crossing the first direction Z, and extend in the third direction crossing both the first direction Z and the second direction X. The first semiconductor region 11, the second semiconductor region 12, and the third semiconductor region 13 are disposed side by side in the first direction Z in the inter-recess region A between the first concave portions 21 adjacent to each other. The plurality of first divisions 11a and the plurality of second divisions 11b are arranged alternately in the third direction Y in the inter-recess region A.

According to the embodiment, the third divisions 12a and the fourth divisions 12b are also alternately arranged in the third direction Y. Accordingly, even at the gate voltage V_{G} where the fourth divisions 12b of the second semiconductor region 12 are in the ON state and the third divisions 12a are in the OFF state, a local temperature rise in the second semiconductor region 12 can be suppressed.

In the semiconductor device 1 of the embodiment, in the two inter-recess regions A adjacent to each other in the second direction X, the first divisions 11a disposed on one side and the first divisions 11a disposed on the other side are arranged in the second direction X. In addition, in the two inter-recess regions A adjacent to each other in the second direction X, the second divisions 11b disposed on one side and the second divisions 11b disposed on the other side are arranged in the second direction X. According to the semiconductor device 1 of the embodiment, the shape of the mask used in the manufacturing process to form the first divisions 11a and the second divisions 11b can be simplified. Eventually, it is possible to manufacture the semiconductor device 1 at low cost.

### Second Embodiment

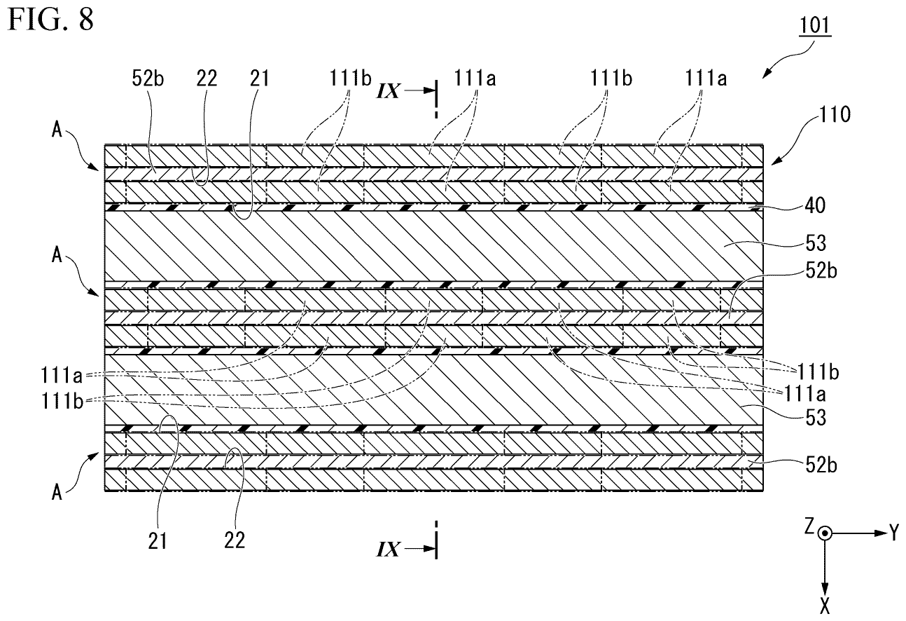

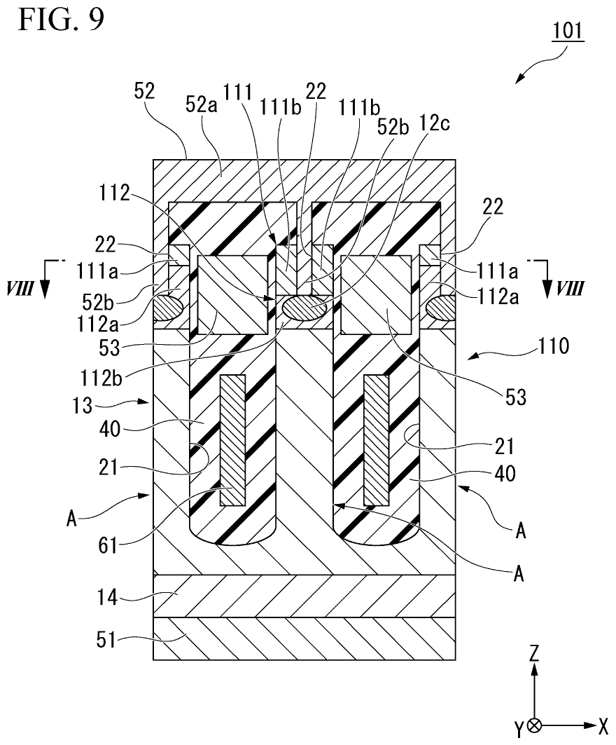

FIG. 8 is a cross-sectional view of a semiconductor device 101 of a second embodiment when seen from above. FIG. 9 is a cross-sectional view of the semiconductor device 101 of the second embodiment along line IX-IX in FIG. 8. Further, FIG. 8 is a cross-sectional view along line VIII-VIII in FIG. 9. The semiconductor device 101 of the embodiment is different from the first embodiment in the arrangement of first divisions 111a and second divisions 111b when seen in the first direction Z. Further, the same components as in the above-mentioned embodiment are designated by the same reference signs, and description thereof will be omitted.

As shown in FIG. 9, like the above-mentioned embodiment, a semiconductor member 110 of the semiconductor device 101 of the embodiment has a first semiconductor region 111 and a second semiconductor region 112 disposed side by side in the first direction Z in the inter-recess region A. In addition, like the above-mentioned embodiment, the first semiconductor region 111 has the first divisions 111a and the second divisions 111b with different depths at lower end portions, and the second semiconductor region 112 has third divisions 112a located below the first divisions 111a and fourth divisions 112b located below the second divisions 111b. Further, as shown in FIG. 8, the plurality of first divisions 111a and the plurality of second divisions 111b are alternately arranged in the third direction Y in the inter-recess region A.

As shown in FIG. 8, in the semiconductor device 101 of the embodiment, in the two inter-recess regions A adjacent to each other in the second direction X, the first divisions 111a disposed on one side and the second divisions 111b disposed on the other side are arranged in the second direction X. In the two inter-recess regions A adjacent to each other in the second direction X, the second divisions 111b disposed on one side and the first divisions 111a disposed on the other side are arranged in the second direction X. Accordingly, in the embodiment, in the neighboring inter-recess regions A, the first divisions 111a and the second divisions 111b are shifted in the third direction Y. In addition, similarly, the third divisions 112a and the fourth divisions 112b are also shifted in the third direction Y. According to the embodiment, at the gate voltage V_{G} where the fourth divisions 112b of the second semiconductor region 112 are in the ON state and the third divisions 112a are in the OFF state, the regions through which current flows are shifted in the neighboring inter-recess regions A, thereby suppressing a localized temperature rise in the second semiconductor region 112.

### Third Embodiment

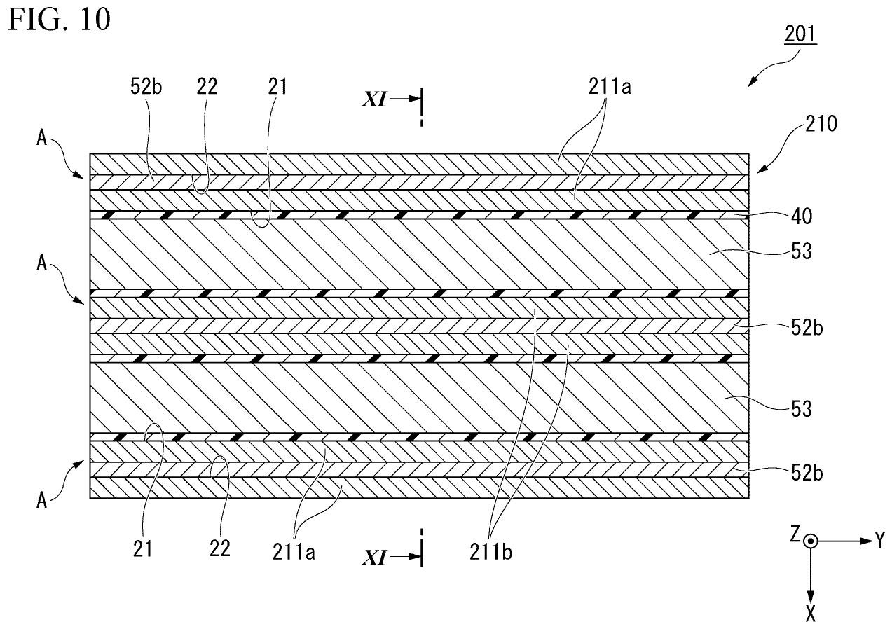

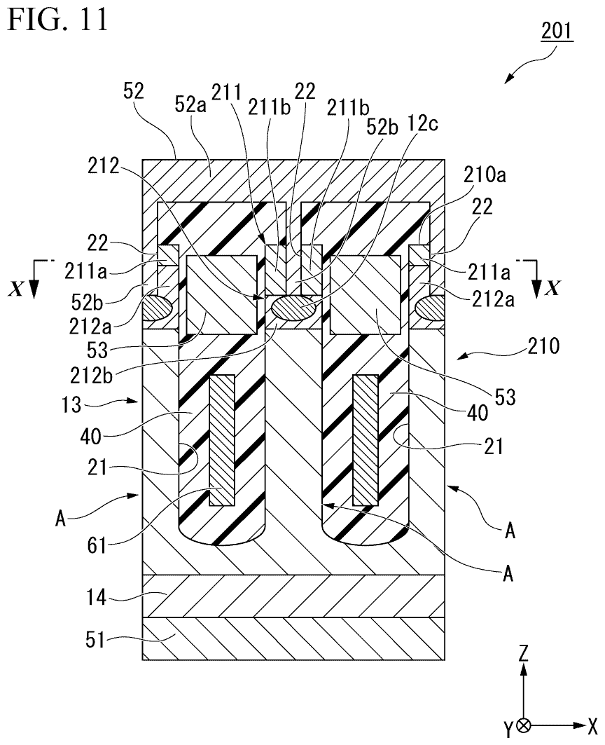

FIG. 10 is a cross-sectional view of a semiconductor device 201 of a third embodiment when seen from above. FIG. 11 is a cross-sectional view of the semiconductor device 201 of the third embodiment along line XI-XI in FIG. 10. Further, FIG. 10 is a cross-sectional view along line X-X in FIG. 11. The semiconductor device 201 of the embodiment is different from the first embodiment in the arrangement of the first divisions 211a and the second divisions 211b when seen in the first direction Z. The first divisions 211a and the second divisions 211b are not arranged alternately in the third direction Y. Further, the same components as in the above-mentioned embodiment are designated by the same reference signs, and description thereof will be omitted.

As shown in FIG. 11, like the above-mentioned embodiment, a semiconductor member 210 of the semiconductor device 201 of the embodiment has a first semiconductor region 211 and a second semiconductor region 212 disposed side by side in the first direction Z of the inter-recess region A. In addition, like the above-mentioned embodiment, the first semiconductor region 211 has the first divisions 211a and the second divisions 211b with different depths at lower end portions, and the second semiconductor region 212 has third divisions 212a located below the first divisions 211a and fourth divisions 212b located below the second divisions 211b.

As shown in FIG. 10, in the semiconductor member 210 of the embodiment, the inter-recess region A in which the first divisions 211a are provided and the inter-recess region A in which the second divisions 211b are provided are arranged in the second direction X. Accordingly, the inter-recess region A in which the third divisions 212a are provided and the inter-recess region A in which the fourth divisions 212b are provided are arranged in the second direction X. According to the embodiment, the first divisions 211a and the second divisions 211b are not arranged in the same inter-recess region A. The first divisions 211a and the second divisions 211b are arranged in different inter-recess regions A. Therefore, at the gate voltage V_{G} where the fourth divisions 212b of the second semiconductor region 212 are in the ON state and the third divisions 212a are in the OFF state, the inter-recess region A through which a current flows and the inter-recess region A through which a current does not flow are arranged alternately in the X direction. For this reason, it is possible to suppress the current from flowing unevenly within the inter-recess region A.

Further, in the embodiment, the inter-recess region A in which the first divisions 211a are provided and the inter-recess region A in which the second divisions 211b are provided are alternately arranged in the second direction X. However, the inter-recess region A in which the first divisions 211a are provided and the inter-recess region A in which the second divisions 211b are provided may be arranged in the second direction X so as to have a ratio other than 1:1 (for example, 2:1).

### Fourth Embodiment

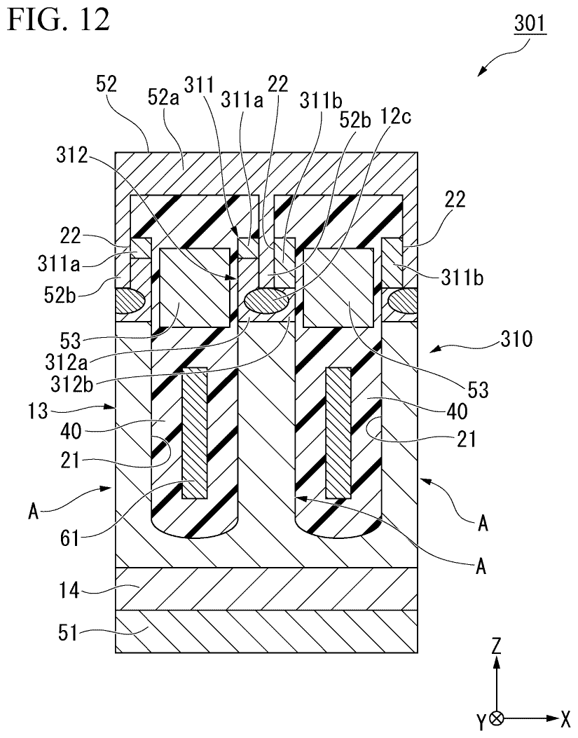

FIG. 12 is a cross-sectional view of a semiconductor device 301 of a fourth embodiment. The semiconductor device 301 of the embodiment is different from the first embodiment in the arrangement of first divisions 311a and second divisions 311b when seen in the first direction Z. Further, the same components as in the above-mentioned embodiment are designated by the same reference signs, and description thereof will be omitted.

As shown in FIG. 12, like the above-mentioned embodiment, a semiconductor member 310 of the semiconductor device 301 of the embodiment has a first semiconductor region 311 and a second semiconductor region 312 disposed side by side in the first direction Z in the inter-recess region A. In addition, like the above-mentioned embodiment, the first semiconductor region 311 has the first divisions 311a and the second divisions 311b with depths at lower end portions, and the second semiconductor region 312 has third divisions 312a located below the first divisions 311a and fourth divisions 312b located below the second divisions 311b.

As shown in FIG. 12, in the semiconductor device 301 of the embodiment, the first divisions 311a and the second divisions 311b are located on one side and the other side in the second direction X of the second concave portions 22 in the inter-recess region A. The first divisions 311a and the second divisions 311b face each other in the second direction X across the source electrode 52. According to the embodiment, the third divisions 312a and the fourth divisions 312b are also located on one side and the other side of the second concave portions 22 in the second direction X, respectively. According to the embodiment, at the gate voltage V_{G} where the fourth divisions 312b of the second semiconductor region 312 are in the ON state and the third divisions 312a are in the OFF state, the inter-recess region A includes a portion through which a current flows and a portion through which a current does not flow, and a local temperature rise in the second semiconductor region 312 can be suppressed.

### Fifth Embodiment

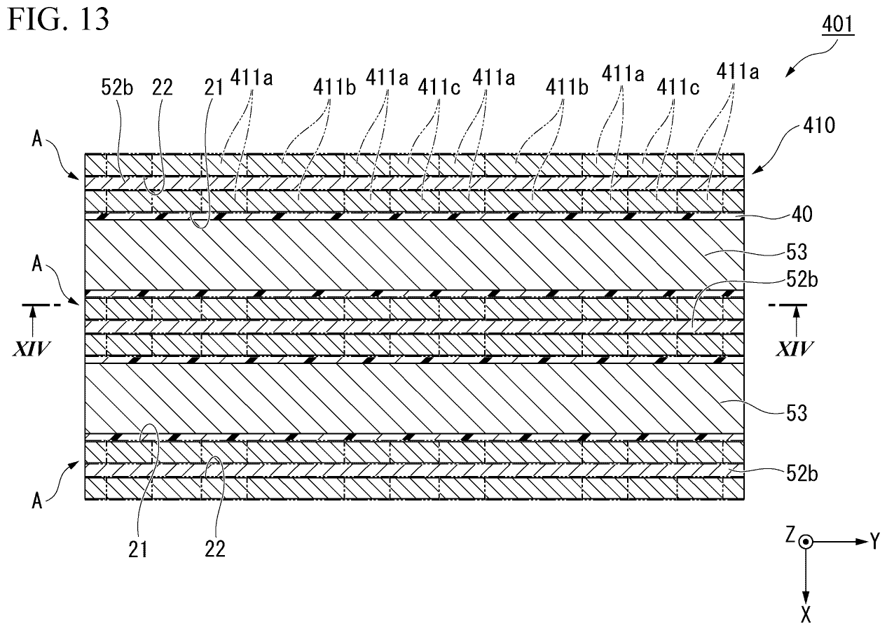

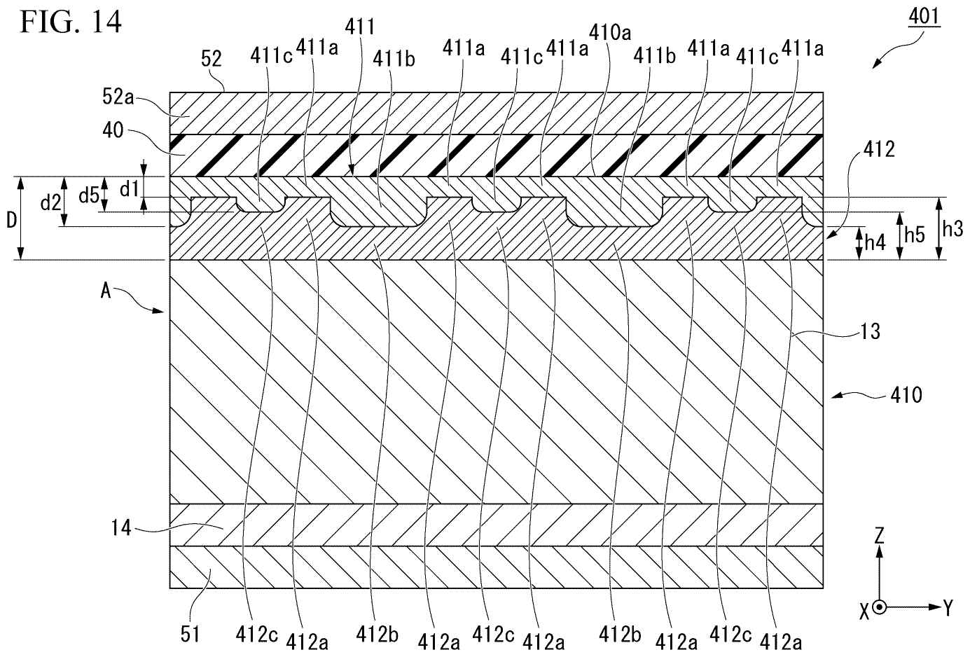

FIG. 13 is a cross-sectional view of a semiconductor device 401 of a fifth embodiment. FIG. 14 is a cross-sectional view of the semiconductor device 401 of the third embodiment along line XIV-XIV in FIG. 13. The semiconductor device 401 of the embodiment is different from the first embodiment in that a first semiconductor region 411 has fifth divisions 411c in addition to first divisions 411a and second divisions 411b. Further, the same components as in the above-mentioned embodiment are designated by the same reference signs, and description thereof will be omitted.

As shown in FIG. 13, like the above-mentioned embodiment, a semiconductor member 410 of the semiconductor device 401 of the embodiment has the first semiconductor region 411 and a second semiconductor region 412. In the semiconductor device 401 of the embodiment, the first semiconductor region 411 has the plurality of first divisions 411a, the plurality of second divisions 411b, and the plurality of fifth divisions 411c when seen in the first direction Z. The first divisions 411a are provided from a surface 410a of the semiconductor member 410 to a position of the first depth d1, and the second divisions 411b are provided from the surface 410a of the semiconductor member 410 to a position of the second depth d2. The fifth divisions 411c are provided from the surface 410a of the semiconductor member 410 to a position of a fifth depth d5.

Like the above-mentioned embodiment, the second depth d2 is greater than the first depth d1. In the embodiment, the fifth depth d5 is a depth between the first depth d1 and the second depth d2. Accordingly, the fifth depth d5 is greater than the first depth d1 and smaller than the second depth d2 (d1<d5<d2).

A lower end of the second semiconductor region 412 of the embodiment is provided below the first semiconductor region 411 and at the depth D from the surface 410a. In the second semiconductor region 412, third divisions 412a are provided below the first divisions 411a, fourth divisions 412b are provided below the second divisions 411b, and sixth divisions 412c are provided below the fifth divisions 411c. A dimension h5 of the sixth division 412c in the first direction Z is smaller than the dimension h3 of the third division 412a in the first direction Z and greater than the dimension h4 of the fourth division 412b in the first direction Z.

According to the embodiment, at the gate voltage V_{G} between the gate voltage V_{G} (the first threshold Vth1 shown in FIG. 7) at which only the fourth divisions 412b are in the ON state and the gate voltage V_{G} (the second threshold Vth2 shown in FIG. 7) at which the entire second semiconductor region 412 is in the ON state, it is possible for the fourth divisions 412b and the sixth divisions 412c to be in the ON state and the third divisions 412a to be in the OFF state. Accordingly, it is possible to finely adjust the shape of the graph showing the relationship between the gate voltage V_{G} and the drain current I_{D}.

Further, as shown in FIG. 13, each of the fifth divisions 411c is disposed in a center of each of the first divisions 411a of the first embodiment. However, arrangement of the divisions is not limited to the embodiment.

According to at least one of the embodiments described above, the first semiconductor region 11, 111, 211, 311 or 411 has the first divisions 11a, 111a, 211a, 311a or 411a, and the second divisions 11b, 111b, 211b, 311b or 411b, which have different depths in the lower end portion, thereby enabling the safety operating area to be expanded.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor member having a first concave portion recessed from a surface in a first direction on a first side to a second side opposite to the first side;
a source electrode located on the first side of the semiconductor member;
a drain electrode located on the second side of the semiconductor member;
a gate electrode, at least a part of which is located in the first concave portion; and
an insulating portion located in the first concave portion and configured to insulate the semiconductor member from the gate electrode,
wherein the semiconductor member includes:
a first semiconductor region of a first conductivity type;
a second semiconductor region of a second conductivity type; and
a third semiconductor region of the first conductivity type,
the first semiconductor region is electrically connected to the source electrode,
the second semiconductor region is located on the second side of the first semiconductor region, at least a part of which faces the gate electrode in a second direction perpendicular to the first direction,
the third semiconductor region is located on the second side of the second semiconductor region,
the first semiconductor region has a plurality of first divisions and a plurality of second divisions when seen in the first direction,
the first divisions are provided from the surface to a position of a first depth,
the second divisions are provided from the surface to a position of a second depth greater than the first depth, and
an end on the second side of the second semiconductor region is provided below the first divisions and the second divisions and at a third depth from the surface.

2. The semiconductor device according to claim 1, wherein a sum of areas of the plurality of first divisions when seen in the first direction is greater than a sum of areas of the plurality of second divisions when seen in the first direction.

3. The semiconductor device according to claim 1, wherein the plurality of first divisions and the plurality of second divisions are periodically disposed when seen in the first direction.

4. The semiconductor device according to claim 3, wherein the first concave portion and the gate electrode are each provided in multiple locations,
a plurality of the first concave portions and a plurality of the gate electrodes are arranged in a second direction crossing the first direction and extend in a third direction crossing both the first direction and the second direction,
the first semiconductor region, the second semiconductor region, and the third semiconductor region are disposed side by side in the first direction in an inter-recess region between the first concave portions adjacent to each other, and
the plurality of first divisions and the plurality of second divisions are alternately arranged in the third direction in the inter-recess region.

5. The semiconductor device according to claim 4, wherein, in the two inter-recess regions adjacent to each other in the second direction, the first divisions disposed on one side and the first divisions disposed on the other side are arranged in the second direction, and
in the two inter-recess regions adjacent to each other in the second direction, the second divisions disposed on one side and the second divisions disposed on the other side are arranged in the second direction.

6. The semiconductor device according to claim 4, wherein, in the two inter-recess regions adjacent to each other in the second direction, the first divisions disposed on one side and the second divisions disposed on the other side are arranged in the second direction, and
in the two inter-recess regions adjacent to each other in the second direction, the second divisions disposed on one side and the first divisions disposed on the other side are arranged in the second direction.

7. The semiconductor device according to claim 3, wherein the first concave portion comprises a plurality of the first concave portions,
the gate electrode comprises a plurality of the gate electrodes,
the inter-recess region comprises a plurality of the inter-recess regions,
the plurality of the first concave portions and the plurality of the gate electrodes are arranged in a second direction crossing the first direction and extend in a third direction crossing the first direction and the second direction,
the first semiconductor region, the second semiconductor region, and the third semiconductor region are disposed side by side in the first direction in the inter-recess region between the first concave portions adjacent to each other, and
among the plurality of the inter-recess regions, those in which the first division is provided and those in which the second division is provided are alternately arranged in the second direction.

8. The semiconductor device according to claim 3, wherein the first concave portion and the gate electrode are each provided in plural locations,
a plurality of the first concave portions and a plurality of the gate electrodes are alternately arranged in a second direction crossing the first direction and extend in a third direction crossing both the first direction and the second direction,
the first semiconductor region, the second semiconductor region, and the third semiconductor region are disposed side by side in the first direction in an inter-recess region between the first concave portions adjacent to each other,
the semiconductor member is provided with a second concave portion located in the inter-recess region and recessed from the surface to the second side,
at least a part of the source electrode is located in the second concave portion, and
the first divisions and the second divisions face each other in the second direction across the source electrode.
